(19) United States
(12) Patent Application Publication
(10) Pub. No.: US 2023/0089367 A1
(43) Pub. Date: Mar. 23, 2023

(54) CONTACT PROBE, INSPECTION APPARATUS, AND INSPECTION METHOD

(71) Applicant: Kioxia Corporation, Tokyo (JP)

(72) Inventors: Masashi NIIMURA, Yokohama (JP); Mitsuhiro OHYA, Ayase (JP)

(73) Assignee: Kioxia Corporation, Tokyo (JP)

(21) Appl. No.: 17/652,956

(22) Filed: Mar. 1, 2022

(30) Foreign Application Priority Data
Sep. 21, 2021 (JP) 2021-153538

(51) Int. Cl. G01R 1/067; G01R 31/28

(52) U.S. Cl. CPC G01R 1/06722; G01R 31/2889; G01R 31/2891

(57) ABSTRACT

A contact probe includes a first plunger, a contact terminal, and a conductive member. The first plunger is contactable with one of an electrode of a semiconductor device and a pad of a test jig. The contact terminal is contactable with the other of the electrode of the semiconductor device and the pad of the test jig. The conductive member covers a part of the first plunger. The conductive member and the first plunger are provided to bring an end portion of the first plunger and the contact terminal into a conduction state when the end portion of the first plunger is pressed by a force smaller than a predetermined force, and bring the end portion of the first plunger and the contact terminal into a nonconduction state when the end portion of the first plunger is pressed by a force equal to or larger than the predetermined force.

### CROSS-REFERENCE TO RELATED APPLICATIONS

This application is based upon and claims the benefit of priority from the prior Japanese Patent Application No. 2021-153538 filed on Sep. 21, 2021; the entire contents of which are incorporated herein by reference.

### FIELD

An embodiment described herein relates generally to a contact probe, an inspection apparatus, and an inspection method.

### BACKGROUND

A test jig such as a test board and an IC socket including a contact probe have been used for a test for a semiconductor device. The IC socket including the contact probe ensures contact of the semiconductor device and the test jig through contraction of a spring on an inside of the contact probe.

In general, in the IC socket including the contact probe, pressure is applied after the semiconductor device is inserted (attached), whereby the spring inside the contact probe contracts and a ball-like electrode provided on, for example, a rear surface of the semiconductor device and a pad of the test jig come into a conduction state.

### BRIEF DESCRIPTION OF THE DRAWINGS

FIG. 1 is a schematic sectional view showing an overall configuration of an inspection apparatus according to an embodiment;

FIG. 2 is a partial cross-sectional view showing a configuration of an IC socket according to a comparative example;

FIG. 3 is a partial cross-sectional view showing a configuration of an IC socket in the present embodiment;

FIG. 4 is an enlarged partial cross-sectional view showing a configuration of a first contact probe;

FIG. 5 is an enlarged partial cross-sectional view showing a configuration of a second contact probe;

FIG. 6 is a partial cross-sectional view showing a state in which the first contact probe comes into conduction/nonconduction states according to pressure; and

FIG. 7 is a partial cross-sectional view showing a state in which the second contact probe comes into the conduction/nonconduction states according to pressure.

### DETAILED DESCRIPTION

A contact probe in the present embodiment includes a first plunger, a contact terminal, and a conductive member. The first plunger is contactable with one of an electrode of a semiconductor device and a pad of a test jig. The contact terminal is contactable with another of the electrode of the semiconductor device and the pad of the test jig. The conductive member covers a part of the first plunger. The conductive member and the first plunger are provided to bring an end portion of the first plunger and the contact terminal into a conduction state when the end portion of the first plunger is pressed by a force smaller than a predetermined force and bring the end portion of the first plunger and the contact terminal into a nonconduction state when the end portion of the first plunger is pressed by a force equal to or larger than the predetermined force.

An embodiment is explained below with reference to the drawings. Note that drawings based on the embodiment are schematic. Relations between thicknesses and widths of respective portions, ratios of the thicknesses and relative angles of the respective portions, and the like are different from real ones. Portions, relations and ratios of dimensions of which are different from one another, are included among the drawings.

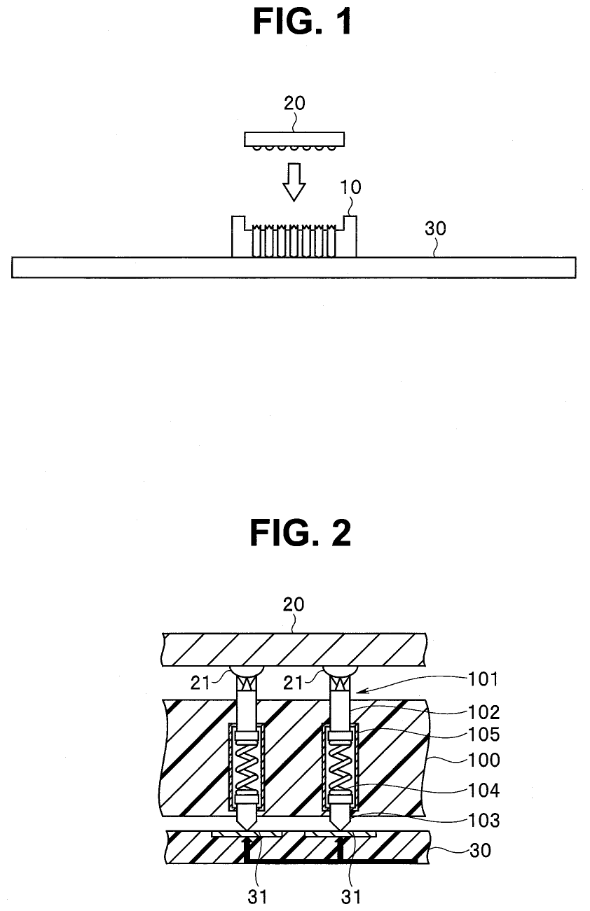

FIG. 1 is a schematic cross-sectional view showing an overall configuration of an inspection apparatus according to an embodiment.

An IC socket 10 shown in FIG. 1 is an inspection apparatus used in inspecting an electric characteristic of a semiconductor device 20 functioning as a test target object. The IC socket 10 electrically connects the semiconductor device 20 and a test jig 30, which is a test board.

The test jig 30 transmits a signal for inspection to the semiconductor device 20 via the IC socket 10 and receives a signal of an inspection result from the semiconductor device 20 via the IC socket 10. The transmission of the signal for inspection to the semiconductor device 20 is performed by, for example, a tester electrically connected to the test jig 30. The tester determines, from the signal indicating the inspection result transmitted from the semiconductor device 20, whether the semiconductor device 20 is a non-defective product or a defective product.

FIG. 2 is a partial cross-sectional view showing a configuration of an IC socket according to a comparative example.

An IC socket 100 in the comparative example includes a plurality of contact probes 101. The contact probes 101 are configured by first plungers 102, second plungers 103, springs 104, and barrels 105, each of which is formed using a conductive material.

The first plungers 102 come into contact with ball-like electrodes 21 provided on a rear surface of the semiconductor device 20. The second plungers 103 come into contact with pads 31 of the test jig 30.

The springs 104 are provided between the first plungers 102 and the second plungers 103, and couple the first plungers 102 and the second plungers 103 to be extendable and contractible. The barrels 105 are tube bodies having a cylindrical shape and house parts of the first plungers 102, parts of the second plungers 103, and the entire springs 104.

In some case, a signal line (a wire) is shared on an inside of the test jig 30 according to, for example, a limitation of the number of pins that can be provided in the test jig 30 and is connected to two pads 31. In the IC socket 100 in the comparative example, when the semiconductor device 20 is attached and predetermined pressure is applied to the semiconductor device 20, all the electrodes 21 come into a conduction state with the pads 31 of the test jig 30.

Therefore, when the same signal line is connected to the two pads 31 in the test jig 30, two electrodes 21 coming into the conduction state with the two pads 31 to which the same signal line is connected cannot be electrically and physically disconnected.

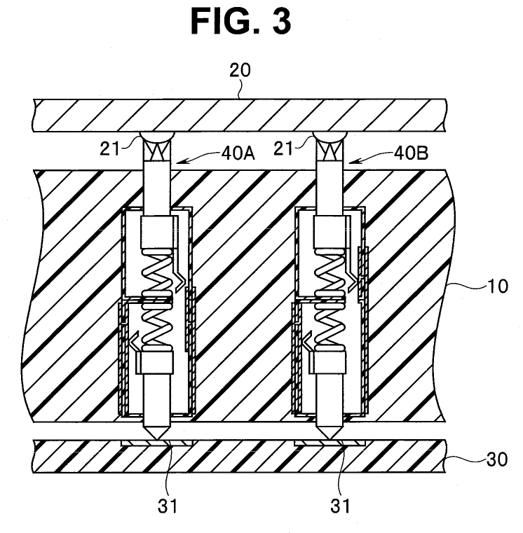

FIG. 3 is a partial cross-sectional view showing a configuration of the IC socket in the present embodiment.

As shown in FIG. 3, the IC socket 10 in the present embodiment includes at least one or more first contact probes 40A and at least one or more second contact probes 40B. Note that disposition of the first contact probe 40A and the second contact probe 40B is not particularly limited and may be any disposition. However, for example, the first contact probe 40A and the second contact probe 40B are disposed to come into contact with the two pads 31 that share the wire in the test jig 30.

When the semiconductor device 20 is attached to the IC socket 10 and pressed by pressure lower than predetermined pressure, the first contact probe 40A brings a first section between the electrode 21 and the pad 31 into a nonconduction state. When the semiconductor device 20 is pressed by pressure equal to or higher than the predetermined pressure, the first contact probe 40A brings the first section between the electrode 21 and the pad 31 into the conduction state.

When the semiconductor device 20 is attached to the IC socket 10 and pressed by pressure lower than the predetermined pressure, the second contact probe 40B brings a second section between the electrode 21 and the pad 31 into the conduction state. When the semiconductor device 20 is pressed by pressure equal to or higher than the predetermined pressure, the second contact probe 40B brings the second section between the electrode 21 and the pad 31 into the nonconduction state.

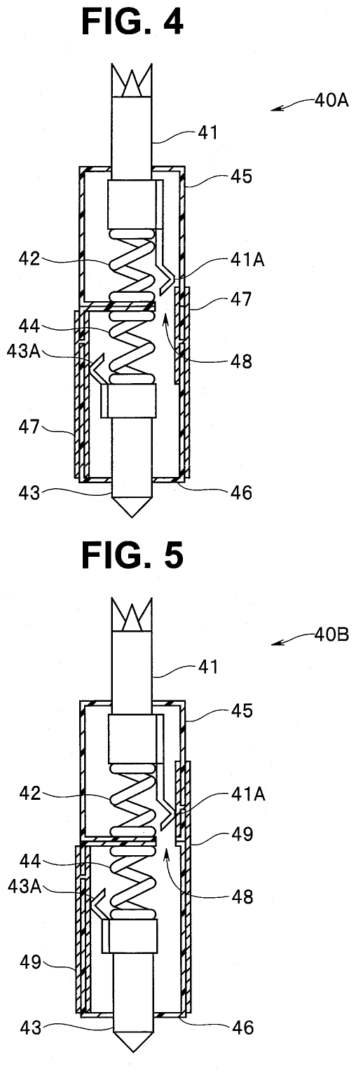

FIG. 4 is an enlarged partial cross-sectional view showing a configuration of the first contact probe. FIG. 5 is an enlarged partial cross-sectional view showing a configuration of the second contact probe. Note that, in FIG. 5, the same components as the components shown in FIG. 4 are denoted by the same reference numerals and signs.

As shown in FIG. 4, the first contact probe 40A includes a first plunger 41, a first spring 42, a second plunger 43, a second spring 44, a first barrel 45, a second barrel 46, and a third barrel 47.

The first plunger 41 includes a first contactor 41 A. The second plunger 43 includes a second contactor 43A. The first spring 42 is provided between the first plunger 41 and the first barrel 45. The second spring 44 is provided between the second plunger 43 and the second barrel 46. The first plunger 41, the first contactor 41A, the second plunger 43, and the second contactor 43A are formed using the conductive material. In the first barrel 45 and the second barrel 46, an opening 48 is provided in a part through which the first contactor 41 A is inserted.

The first barrel 45 is a first tube body having a cylindrical shape formed using a nonconductive material and houses a part of the first plunger 41 and the entire first spring 42.

The second barrel 46 is a second tube body having a cylindrical shape formed using the nonconductive material and houses a part of the second plunger 43 and the entire second spring 44.

The third barrel 47 is a first conductive member formed using the conductive material and is formed to cover parts of an inside and an outside of the first barrel 45 and parts of an inside and an outside of the second barrel 46.

Since the first barrel and the second barrel are formed by the nonconductive material, the first plunger 41 and the first spring 42, and the second plunger 43 and the second spring 44 are not electrically connected. Therefore, when the semiconductor device 20 is attached to the IC socket 10 and pressed by pressure lower than predetermined pressure, the electrode 21 of the semiconductor device 20 and the pad 31 of the test jig 30 come into the nonconduction state.

When the semiconductor device 20 is attached to the IC socket 10 and pressed by pressure equal to or higher than the predetermined pressure, the first spring 42 contracts and the first contactor 41 A of the first plunger 41 comes into contact with the third barrel 47 formed by the conductive material. Since the third barrel 47 is in contact with the second contactor 43A of the second plunger 43, the first plunger 41 and the second plunger 43 conduct with each other, and the electrode 21 of the semiconductor device 20 and the pad 31 of the test jig 30 come into the conduction state.

As shown in FIG. 5, the second contact probe 40B is configured using a third barrel 49 instead of the third barrel 47 of the first contact probe 40A. The third barrel 49 is a second conductive member formed using the conductive material, and is formed to cover parts of an inside and an outside of the first barrel 45 and parts of an inside and an outside of the second barrel 46.

As shown in FIG. 5, the third barrel 49 is provided over an entire up-down direction of a left side surface in the second barrel 46. Therefore, even if the second spring 44 contracts and the second contactor 43A moves up and down, the third barrel 49 is provided over an entire movable range of the second contactor 43A. The third barrel 49 is provided in a part on a lower side of a right side surface in the first barrel 45. Therefore, a length of the third barrel 49 in a moving direction of the first plunger 41 in the first barrel 45 is smaller than a length of the third barrel 49 in a moving direction of the second plunger 43 in the second barrel 46.

When the semiconductor device 20 is attached to the IC socket 10 and pressed by pressure lower than predetermined pressure, the first contactor 41A of the first plunger 41 is in contact with the third barrel 49 formed by the conductive material. Since the third barrel 49 is in contact with the second contactor 43A of the second plunger 43, the first plunger 41 and the second plunger 43 conduct and the electrode 21 of the semiconductor device 20 and the pad 31 of the test jig 30 come into the conduction state.

When the semiconductor device 20 is attached to the IC socket 10 and pressed by pressure equal to or higher than the predetermined pressure, the first spring 42 contracts and the first contactor 41A of the first plunger 41 does not come into contact with the third barrel 49 formed by the conductive material. Consequently, the electrode 21 of the semiconductor device 20 and the pad 31 of the test jig 30 come into the nonconduction state.

In this way, the conduction state and the nonconduction state of the first contact probe 40A and the second contact probe 40B are switched by the pressure applied to the semiconductor device 20. The pressure applied to the semiconductor device 20 is adjusted by, for example, a handler used when the semiconductor device 20 is attached to the IC socket 10.

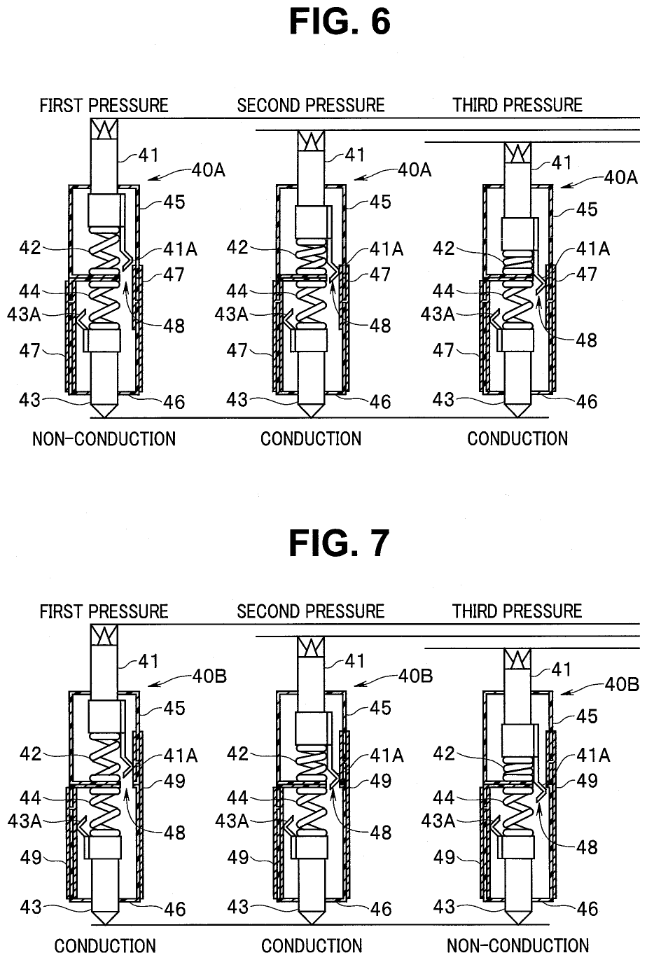

A state in which the conduction state and the nonconduction state are switched by the pressure is explained with reference to FIGS. 6 and 7. FIG. 6 is a partial cross-sectional view showing a state in which the first contact probe comes into the conduction/nonconduction states according to the pressure. FIG. 7 is a partial cross-sectional view showing a state in which the second contact probe comes into the conduction/nonconduction states according to the pressure.

As shown in FIG. 6, in the first contact probe 40A, when the semiconductor device 20 is pressed by first pressure, the first contactor 41A and the third barrel 47 do not come into contact. Therefore, the electrode 21 of the semiconductor device 20 and the pad 31 of the test jig 30 are in the nonconduction state.

In the first contact probe 40A, when the semiconductor device 20 is pressed by second pressure higher than the first pressure, the first contactor 41A and the third barrel 47 come into contact. Therefore, the first contactor 41A is connected to the second contactor 43A provided in the second plunger 43 via the third barrel 47 formed by the conductive material, whereby the electrode 21 of the semiconductor device 20 and the pad 31 of the test jig 30 come into the conduction state.

In the first contact probe 40A, when the semiconductor device 20 is pressed by third pressure higher than the second pressure, the first contactor 41A and the third barrel 47 come into contact, as in the case of the second pressure. Therefore, the electrode 21 of the semiconductor device 20 and the pad 31 of the test jig 30 come into the conduction state.

As shown in FIG. 7, in the second contact probe 40B, when the semiconductor device 20 is pressed by the first pressure, the first contactor 41A and the third barrel 49 come into contact. Therefore, the first contactor 41A is connected to the second contactor 43A provided in the second plunger 43 via the third barrel 49 formed by the conductive material, whereby the electrode 21 of the semiconductor device 20 and the pad 31 of the test jig 30 come into the conduction state.

In the second contact probe 40B, when the semiconductor device 20 is pressed by the second pressure, the first contactor 41A and the third barrel 49 come into contact, as in the case of the first pressure. Therefore, the electrode 21 of the semiconductor device 20 and the pad 31 of the test jig 30 come into the conduction state.

In the second contact probe 40B, when the semiconductor device 20 is pressed by the third pressure, the contact of the first contactor 41A and the third barrel 49 is released and the first contactor 41A and the third barrel 49 come into a noncontact state. Therefore, the electrode 21 of the semiconductor device 20 and the pad 31 of the test jig 30 come into the nonconduction state.

In this way, in the first contact probe 40A, the electrode 21 and the pad 31 come into the nonconduction state at the first pressure, and the electrode 21 and the pad 31 come into the conduction state at the second pressure and the third pressure. In the second contact probe 40B, the electrode 21 and the pad 31 come into the conduction state at the first pressure and the second pressure, and the electrode 21 and the pad 31 come into the nonconduction state at the third pressure.

As explained above, when the semiconductor device 20 is pressed against the IC socket 10 at the first pressure, the electrode 21 in contact with the first contact probe 40A comes into the nonconduction state with the pad 31 and the electrode 21 in contact with the second contact probe 40B comes into the conduction state with the pad 31.

When the semiconductor device 20 is pressed against the IC socket 10 at the second pressure, the electrode 21 in contact with the first contact probe 40A and the second contact probe 40B comes into the conduction state with the pad 31.

Further, when the semiconductor device 20 is pressed against the IC socket 10 at the third pressure, the electrode 21 in contact with the first contact probe 40A comes into the conduction state with the pad 31 and the electrode 21 in contact with the second contact probe 40B comes into the nonconduction state with the pad 31.

In this way, the IC socket 10 in the present embodiment can switch the conduction state and the nonconduction state for each of the first contact probe 40A and the second contact probe 40B according to pressure (a press-in amount) for pressing the semiconductor device 20 against the IC socket 10.

As shown in FIGS. 6 and 7, a contract amount of the first spring 42 connected to the first plunger 41 is set larger than a contract amount of the second spring 44 connected to the second plunger 43 under the same pressure. In other words, a spring constant of the first spring 42 connected to the first plunger 41 is set smaller than a spring constant of the second spring 44 connected to the second plunger 43.

By using the IC socket 10 in the present embodiment, one of the first contact probe 40A and the second contact probe 40B can be brought into the nonconduction state according to the pressure for pressing the semiconductor device 20 against the IC socket 10. Therefore, it is possible to use the shared test jig 30 without changing wiring specifications of the test jig 30.

Even when a leak failure or an open failure occurs in the electrodes 21 connected to the pads 31 to which the same signal line is connected, one of the first contact probe 40A and the second contact probe 40B can be brought into the nonconduction state according to the pressure for pressing the semiconductor device 20 against the IC socket 10. Therefore, it is possible to easily specify the electrode 21 in which the failure occurs.

In the above description, “pressure” means an applied force per unit area of a target object to which a force is applied, but is substantially synonymous with force.

Further, an aspect explained below is conceivable in the present embodiment. In other words, a contact probe includes a first plunger configured to come into contact with an electrode of a semiconductor device, a second plunger configured to come into contact with a pad of a test jig, and a conductive member configured to bring the electrode and the pad into a conduction state when the semiconductor device is pushed in with a push-in amount smaller than a predetermined push-in amount and bring the electrode and the pad into a nonconduction state when the semiconductor device is pushed in with a push-in amount equal to or larger than the predetermined push-in amount.

While certain embodiments have been described, these embodiments have been presented by way of example only, and are not intended to limit the scope of the inventions. Indeed, the novel devices and systems described herein may be embodied in a variety of other forms; furthermore, various omissions, substitutions and changes in the form of the devices and systems described herein may be made without departing from the spirit of the inventions. The accompanying claims and their equivalents are intended to cover such forms or modifications as would fall within the scope and spirit of the inventions.

What is claimed is:

1. A contact probe compri sing:
a first plunger contactable with one of an electrode of a semiconductor device and a pad of a test jig;
a contact terminal contactable with another of the electrode of the semiconductor device and the pad of the test jig; and
a conductive member covering a part of the first plunger, wherein
the conductive member and the first plunger are provided to bring an end portion of the first plunger and the contact terminal into a conduction state when the end portion of the first plunger is pressed by a force smaller than a predetermined force and bring the end portion of the first plunger and the contact terminal into a nonconduction state when the end portion of the first plunger is pressed by a force equal to or larger than the predetermined force.

2. The contact probe according to claim 1, further comprising:
a first tube body covering a part of the first plunger;
a second plunger including the contact terminal; and
a second tube body covering a part of the second plunger, wherein
the conductive member is formed to cover a part of an inside and a part of an outside of the first tube body and a part of an inside and a part of an outside of the second tube body.

3. The contact probe according to claim 1, wherein
the first plunger includes a first contactor, and
the first contactor comes into contact with the conductive member when the end portion of the first plunger is pressed by the force smaller than the predetermined force and does not come into contact with the conductive member when the end portion of the first plunger is pressed by the force equal to or larger than the predetermined force.

4. The contact probe according to claim 2, wherein
the first plunger includes a first contactor, and
the first contactor comes into contact with the conductive member when the end portion of the first plunger is pressed by the force smaller than the predetermined force and does not come into contact with the conductive member when the end portion of the first plunger is pressed by the force equal to or larger than the predetermined force.

5. The contact probe according to claim 2, further comprising:
a first spring connected to the first plunger; and
a second spring connected to the second plunger, wherein
the first spring and the first plunger are insulated from each other, and
the second spring and the second plunger are insulated from each other.

6. The contact probe according to claim 5, wherein a spring constant of the first spring is smaller than a spring constant of the second spring.

7. The contact probe according to claim 2, wherein a length of the conductive member in a moving direction of the first plunger in the first tube body is smaller than a length of the conductive member in a moving direction of the second plunger in the second tube body.

8. The contact probe according to claim 2, wherein
the second plunger includes a second contactor, and
at least a part of the conductive member is provided in a movable region of the second contactor in the second tube body.

9. The contact probe according to claim 2, wherein
surfaces of the first tube body and the second tube body are insulative and a surface of the conductive member is conductive, and
the conductive member pierces through the first tube body and the second tube body in a part and is provided on both of an inner side surface and an outer side surface of the first tube body and provided on both of an inner side surface and an outer side surface of the second tube body.

10. An inspection apparatus that switches a conduction state and a nonconduction state of each of a first section between a first electrode of a semiconductor device and a first pad of a test jig and a second section between a second electrode of the semiconductor device and a second pad of the test jig, the inspection apparatus comprising:
a first contact probe including:
a first plunger contactable with one of the first electrode and the first pad;
a first contact terminal contactable with another of the first electrode and the first pad; and
a first conductive member covering a part of the first plunger,
the first conductive member and the first plunger being provided to bring an end portion of the first plunger and the first contact terminal into a nonconduction state when the end portion of the first plunger is pressed by a force smaller than a first predetermined force and bring the end portion of the first plunger and the first contact terminal into a conduction state when the end portion of the first plunger is pressed by a force equal to or larger than the first predetermined force; and
a second contact probe including:
a second plunger contactable with one of the second electrode and the second pad;
a second contact terminal contactable with another of the second electrode and the second pad; and
a second conductive member covering a part of the second plunger,
the second conductive member and the second plunger being provided to bring an end portion of the second plunger and the second contact terminal into a conduction state when the end portion of the second plunger is pressed by a force smaller than a second predetermined force and bring the end portion of the second plunger and the second contact terminal into a nonconduction state when the end portion of the second plunger is pressed by a force equal to or larger than the second predetermined force.

11. The inspection apparatus according to claim 10, wherein
the first contact probe brings the first electrode and the first pad into the nonconduction state when the semiconductor device is pressed by a first force and brings the first electrode and the first pad into the conduction state when the semiconductor device is pressed by a second force larger than the first force and when the semiconductor device is pressed by a third force larger than the second force, and
the second contact probe brings the second electrode and the second pad into the conduction state when the semiconductor device is pressed by the first force and when the semiconductor device is pressed by the second force and brings the second electrode and the second pad into the nonconduction state when the semiconductor device is pressed by the third force.

12. The inspection apparatus according to claim 10, wherein the first predetermined force and the second predetermined force are equal.

13. The inspection apparatus according to claim 10, wherein the second predetermined force is larger than the first predetermined force.

14. An inspection method using a first contact probe configured to bring a first electrode of an inspection target device and a first pad of a test jig into a nonconduction state when the inspection target device is pressed by a first force smaller than a predetermined force and bring the first electrode and the first pad into a conduction state when the inspection target device is pressed by a second force equal to or larger than the predetermined force and a second contact probe configured to bring a second electrode of the inspection target device and a second pad of the test jig into the conduction state when the inspection target device is pressed by the first force and bring the second electrode and the second pad into the nonconduction state when the inspection target device is pressed by a third force larger than the second force, comprising:
pressing the inspection target device with the first force to perform a first inspection concerning the second electrode;
pressing the inspection target device with the second force to perform a second inspection concerning the first electrode and the second electrode; or
pressing the inspection target device with the third force to perform a third inspection concerning the first electrode.

15. The inspection method according to claim 14, wherein the third inspection is performed after the first inspection is performed.
